(19) United States
(12) Patent Application Publication
(10) Pub. No.: US 2021/0376824 A1
(43) Pub. Date: Dec. 2, 2021

(54) METHOD AND APPARATUS FOR AVOIDING PARASITIC OSCILLATION IN A PARALLEL SEMICONDUCTOR SWITCH

(71) Applicant: Murata Manufacturing Co., Ltd., Nagaokakyo-shi (JP)

(72) Inventor: Chuipong LIU, Hong Kong (CN)

(21) Appl. No.: 17/333,171

(22) Filed: May 28, 2021

(30) Foreign Application Priority Data
Jun. 1, 2020 (CN) 202010486888.X

(51) Int. Cl. H03K 17/16; H02M 1/38

(52) U.S. Cl. CPC H03K 17/161; H02M 1/38

(57) ABSTRACT

A method for avoiding parasitic oscillation in a parallel semiconductor switch includes allowing only one of the plurality of power components to control a turn-on transition of the semiconductor switch and allowing only one of the plurality of power components to control a turn-off transition of the semiconductor switch, by setting unbalanced driving impedances for the plurality of power components coupled in parallel. Parasitic oscillation in a switch transition may be avoided without impedance matching, and the switch transition may provide a relatively small impact on switch characteristics.

### CROSS REFERENCE TO RELATED APPLICATIONS

This application claims the benefit of priority to Chinese Patent Application No. 202010486888.X filed Jun. 1, 2020. The entire contents of this application are hereby incorporated herein by reference.

### BACKGROUND OF THE INVENTION

### 1. Field of the Invention

The present disclosure relates to a parallel semiconductor switch, and more specifically, to a method and apparatus for avoiding parasitic oscillation in a parallel semiconductor switch.

### 2. Description of the Related Art

A switching mode power supply is a high-frequency apparatus for electric energy conversion, which periodically turns on and turns off an electronic switching component by using a power semiconductor component (including but not limited to metal semiconductor field effect transistors MOSFET, bipolar transistor BJT or insulated gate bipolar transistor IGBT, etc.) in a control circuit. Pulse modulation is implemented on an input voltage by the power semiconductor component (hereinafter referred to as power component), so as to achieve voltage conversion, adjustable output voltage and automatic voltage stabilization. Therefore, the switching mode power supply is also called a power converter.

In a field requiring large currents, power semiconductor components (such as MOSFETs) provided as a switch in a power converter may operate in parallel (the switch is also called a parallel semiconductor switch, and a corresponding power supply is called a power supply operated by the parallel switch). This may reduce conduction loss, reduce a thermal resistance to a radiator by increasing surface area, and is scalable for high-power processing.

It is not uncommon that power supplies operated by parallel switches fail to operate. The problems seem to occur randomly. After replacing the semiconductor switch, the problems may sometimes be solved, but sometimes still exist in the converter unit. Generally, no overstress is observed in a power component during a steady-state operation. Detailed analysis shows that parasitic oscillation may occur in a switch transition period, depending on a combination of power components installed to operate in parallel. The parasitic oscillation may generate internal overstress, which is not easy to observe outside the component. When parasitic oscillation occurs, the internal overstress may destroy a relatively weak control terminal (such as a junction between a gate of the MOSFET and a source of the MOSFET), leading to problems.

In a switch transition period, switching current is redistributed among power components, triggering parasitic oscillation. Therefore, parasitic oscillation is prone to occur in parallel operations of power components. The redistribution of switching current is usually caused by a slight difference in turn-on times between components or turn-off times between components (due to different turn-on thresholds and turn-off thresholds and/or different driving impedances).

The components are turned on at different times when operated in a linear region of a switch transient. The parasitic oscillation depends on parasitic parameters of the power components operated in parallel, such that potential problems may not be observed in a development stage. However, problems usually occur after the power components are in production. This leads to potential reliability problems in the parallel operation of power components.

According to an existing solution, all driving impedances of power components are matched, so that all power components coupled in parallel are turned on and turned off at a same time. However, the solution is impractical in mass production.

According to another existing solution, the driving resistance is increased to suppress the parasitic oscillation, but this will increase switching loss and switching duration.

Therefore, a solution to avoid parasitic oscillation in a parallel semiconductor switch is needed.

### SUMMARY OF THE INVENTION

Preferred embodiments of the present invention introduce unbalanced driving impedances into parallel semiconductor switches. In this way, only one of the plurality of power components coupled in parallel is turned on, and only one of the plurality of power components coupled in parallel is turned off in a switch transition period. There is no redistribution of switch current when the components are operated in the linear region, thus preventing parasitic oscillation between power components operated in parallel.

According to a preferred embodiment of the present invention, a method for controlling a semiconductor switch, which includes a plurality of power components coupled in parallel, includes allowing only one of the plurality of power components to control a turn-on transition of the semiconductor switch and allowing only one of the plurality of power components to control a turn-off transition of the semiconductor switch, by setting unbalanced driving impedances for the plurality of power components coupled in parallel.

According to a preferred embodiment of the present invention, a semiconductor switch includes a plurality of power components coupled in parallel. The plurality of power components coupled in parallel include unbalanced control-terminal driving impedances, only one of the plurality of power components is allowed to control a turn-on transition of the semiconductor switch, and only one of the plurality of power components is allowed to control a turn-off transition of the semiconductor switch.

In some preferred embodiments of the present invention, the power component may be a metal semiconductor field effect transistor MOSFET. In some preferred embodiments of the present invention, the power component may be a bipolar transistor BJT. In some preferred embodiments of the present invention, the power component may be an insulated gate bipolar transistor IGBT.

In some preferred embodiments of the present invention, the allowing only one of the plurality of power components to control a turn-on transition of the semiconductor switch and the allowing only one of the plurality of power components to control a turn-off transition of the semiconductor switch includes one of:
turning on the power component controlling the turn-on transition in response to turning on the semiconductor switch, and turning on other power components after the power component controlling the turn-on transition is operated in a saturation region; and
turning off the power component controlling the turn-off transition after other power components are operated in a cutoff region, in response to turning off the semiconductor switch.

In some preferred embodiments of the present invention, the turning on of the power component controlling the turn-on transition in response to turning on the semiconductor switch, and the turning on of the other power components after the power component controlling the turn-off transition is operated in a saturation region is implemented by setting a conduction driving impedance of the power component controlling the turn-on transition to be lower than a conduction driving impedance of other power components. A conduction driving impedance is a driving impedance of a control terminal of a power component in response to turning on the semiconductor switch.

Optionally, the conduction driving impedances of the plurality of power components coupled in parallel satisfies:

$$\frac{{R}_{g\_other \_on}}{{R}_{g\_on}} > \frac{{V}_{drv} - {V}_{th\_min}}{{V}_{drv} - {V}_{th\_max}} \cdot \frac{{C}_{dg\_max}}{{C}_{dg\_min}} ,$$

wherein R_{go_on} is the conduction driving impedance of the power component controlling the turn-on transition of the semiconductor switch, R_{g_other_on} is the conduction driving impedance of other power components, V_{drv} is a conduction driving voltage of a power component, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

In some preferred embodiments of the present invention, the turning off of the power component controlling the turn-off transition after the other power components are operated in a cutoff region, in response to turning off the semiconductor switch is implemented by setting a cutoff driving impedance for the power component controlling the turn-off transition to be greater than a cutoff driving impedance of the other power components. A cutoff driving impedance is a driving impedance of a control terminal of a power component in response to turning off the semiconductor switch.

Optionally, the cutoff driving impedance of the plurality of power components coupled in parallel satisfies:

$$\frac{{R}_{g\_off}}{{R}_{g\_other \_off}} > \frac{{C}_{dg\_max}}{{C}_{dg\_min}} \cdot \frac{{V}_{th\_max}}{{V}_{th\_min}} ,$$

wherein R_{g_off} is the cutoff driving impedance of the power component controlling the turn-off transition of the semiconductor switch, R_{g_other_off} is the cutoff driving impedance of other power components, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

In some preferred embodiments of the present invention, for the plurality of power components, at least a control terminal of the power component controlling the turn-on transition is coupled to a parallel driving circuit, and the parallel driving circuit includes:
a first branch including a diode and a first impedance; and
a second branch including a diode and a second impedance.

In some preferred embodiments of the present invention, for the plurality of power components, at least a control terminal of the power component controlling the turn-off transition is coupled to a parallel driving circuit, and the parallel driving circuit includes:
a first branch including a diode and a third impedance; and
a second branch including a diode and a fourth impedance.

In some preferred embodiments of the present invention, the power component controlling the turn-on transition of the semiconductor switch is different from the power component controlling the turn-off transition of the semiconductor switch.

In other preferred embodiments of the present invention, the power component controlling the turn-on transition of the semiconductor switch may be same as the power component controlling the turn-off transition of the semiconductor switch.

According to preferred embodiments of the present invention, parasitic oscillation in a switch transition may be avoided without impedance matching, and the switch transition may provide a relatively small impact on switch characteristics (such as switch loss and switch speed).

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 schematically shows a diagram of a parallel semiconductor switch according to a preferred embodiment of the present invention.

FIG. 2 schematically shows a diagram of a parallel semiconductor switch according to another preferred embodiment of the present invention.

### DETAILED DESCRIPTION OF THE PREFERRED EMBODIMENTS

Preferred embodiments of the present invention will be described in detail below with reference to the drawings. The same or corresponding elements and component are denoted by the same reference characters in the drawings.

The present invention should not be limited to the specific preferred embodiments described below. In addition, for brevity, detailed descriptions of well-known technologies that are not directly related to preferred embodiments of the present invention are omitted to prevent confusion in the understanding of the preferred embodiments of the present invention.

In order to avoid parasitic oscillation in a parallel semiconductor switch, preferred embodiments of the present invention propose to ensure that only one of a plurality of power components operated in parallel is turned on, and only one of the plurality of power components operated in parallel is turned off in a switch transition period of a parallel semiconductor switch. That is, only one power component controls a turn-on transition of the switch, and only one power component controls a turn-off transition of the switch.

The power component controlling the turn-on transition of the switch may be same as the power component controlling the turn-off transition of the switch. The power component controlling the turn-on transition of the switch may be different from the power component controlling the turn-off transition of the switch. Switching loss may be concentrated in selected components that control the turn-on transition and the turn-off transition. Therefore, in most cases, it is optional, but not limited, to select different components to control the turn-on transition and the turn-off transition respectively, so that heat generated by switching loss may be shared.

In the following preferred embodiments of the present invention, MOSFETs are mainly used as an example of a power semiconductor component. However, it should be understood that the preferred embodiments of the present invention are also applicable to switches including other types of power semiconductor components coupled in parallel, such as, for example, insulated gate bipolar transistors IGBT or bipolar transistor BJT, etc.

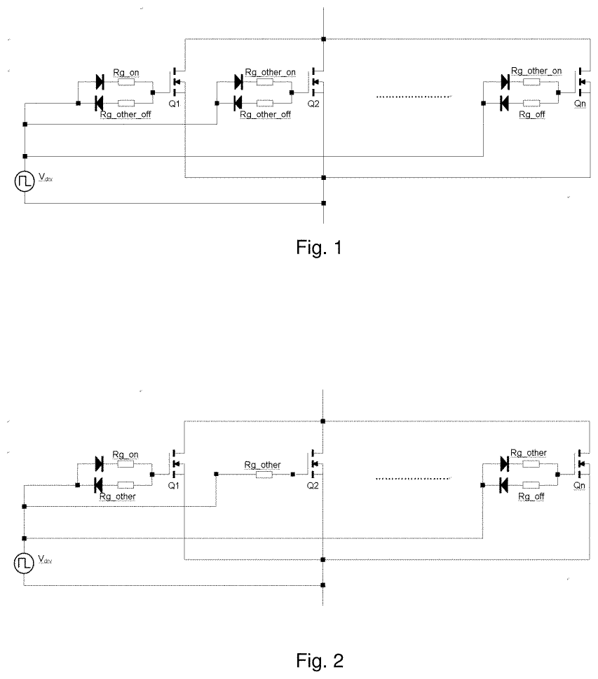

FIG. 1 schematically shows a diagram of a parallel semiconductor switch according to a preferred embodiment of the present invention.

As shown in FIG. 1, the parallel semiconductor switch includes a plurality of power components Q1, Q2 . . . Qn. It should be understood that, although only three power components are shown in FIG. 1, the parallel semiconductor switch may include more or less (such as two) power components. The preferred embodiments of the present invention are not limited to the number of power components shown in FIG. 1. In addition, the power component is shown as a MOSFET in FIG. 1. While in other preferred embodiments, the power component may further be other power semiconductor components, such as, for example, a bipolar transistor BJT.

In the example of FIG. 1, power components controlling the turn-on and turn-off transitions are selected by using unbalanced (i.e., different) driving impedances. Specifically, in the example, Q1 is selected as the power component controlling the turn-on transition, and Qn is selected as the power component controlling the turn-off transition.

For brevity of design and description, a driving circuit for each power component Qi (i=1, 2 . . . ) includes two branches. Diodes are configured to allow the two branches to work during a turn-on period of the switch and a turn-off period of the switch, respectively. Due to the configuration of the diodes in the driving circuit shown in FIG. 1, R_{go_on} is a conduction driving impedance of the selected power component Q1 controlling the turn-on transition, and R_{g_other_on} is a conduction driving impedance of all other power components coupled in parallel. In the present preferred embodiment of the present invention, a conduction driving impedance is a driving impedance of a control terminal of a power component when turning on the switch, such as a driving impedance of a gate of a MOSFET Qi (i=1, 2 . . . ) when turning on the switch shown in FIG. 1.

R_{g_off} is a cutoff driving impedance of the selected power component Qn controlling the turn-off transition, and R_{g_other_off} is a cutoff driving impedance of all other power components coupled in parallel. In preferred embodiments of the present invention, a cutoff driving impedance is a driving impedance of a control terminal of a power component when turning off the switch, such as a driving impedance of a gate of a MOSFET Qi (i=1, 2 . . . ) when turning off the switch shown in FIG. 1.

In this example, to ensure that the component Q1 selected to control the turn-on transition is the only component conductive in a turn-on transition of the switch, the conduction driving impedance of the component may be determined according to Miller effect equation. Based on Miller effect, all other power components Qj (j≠1) coupled in parallel are maintained cutoff when the selected power component Q1 is in the turn-on transition, according to a falling slope of a voltage VDS between a drain of Q1 and a source of Q1. The following formula (1) may be achieved.

$$\frac{{R}_{g\_other \_on}}{{R}_{g\_on}} > \frac{{V}_{drv} - {V}_{th\_min}}{{V}_{drv} - {V}_{th\_max}} \cdot \frac{{C}_{dg\_max}}{{C}_{dg\_min}} \qquad ( 1 )$$

wherein R_{go_on} is the conduction driving impedance of the power component controlling the turn-on transition of the switch (i.e., Q1 in this example), R_{g_other_on} is the conduction driving impedance of other power components, V_{drv} is a conduction driving voltage of a power component, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

If the conduction driving impedances satisfies formula (1), only the selected power component Q1 may participate in the turn-on transition of the switch, and all other power components coupled in parallel may only be turned on as a zero voltage switch (ZVS) after the turn-on transition.

It should be understood that the conduction driving impedances R_{g_other_on} of other power components shown in FIG. 1 may have a same value or may have different values. As long as each of the conduction driving impedances R_{g_other_on} of other power components satisfies the formula (1), it may be ensured that the selected component Q1 for controlling the turn-on transition is the only component conductive in the turn-on transition.

In this example, to ensure that the component Qn selected to control the turn-off transition is the only component to be turned off in a turn-off transition of the switch, the component Qn should be a component with a largest cutoff driving impedance R_{g_off} and should be turned off last. This means that all other components coupled in parallel include relatively low cutoff driving impedances and may be turned off as a ZVS before Qn starts to be turned off. In addition, in order to avoid the other components being conductive in the turn-off transition of the selected component Qn, the cutoff driving impedance may be determined according to Miller effect equation. Based on Miller effect, all other power components Qj (j≠n) coupled in parallel are maintained cutoff when the selected power component Qn is in the turn-off transition, according to a rising slope of a voltage VDS of Qn. The following formula (2) may be achieved.

$$\frac{{R}_{g\_off}}{{R}_{g\_other \_off}} > \frac{{C}_{dg\_max}}{{C}_{dg\_min}} \cdot \frac{{V}_{th\_max}}{{V}_{th\_min}} \qquad ( 2 )$$

wherein R_{g_off} is the cutoff driving impedance of the power component controlling the turn-off transition of the switch (i.e., Qn in this example), R_{g_other_off} is the cutoff driving impedance of other power components, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

If the conduction driving impedances satisfies formula (2), only the selected power component Qn may participate in the turn-off transition of the switch, and all other power components coupled in parallel may already be turned off as a ZVS before the turn-off transition.

It should be understood that the cutoff driving impedances R_{g_other_off} of other power components shown in FIG. 1 may have a same value or may have different values. As long as each of the cutoff driving impedances R_{g_other_off} of other power components satisfies the formula (2), it may be ensured that the selected component Qn for controlling the turn-off transition is the only component to be turned off in the turn-off transition.

According to preferred embodiments of the present invention, the parasitic oscillation caused by the parallel operation of power components may be avoided. In addition, for parallel operation, there is no need to sacrifice the switch characteristics (for example, not significantly affecting switch loss and switch speed). A desired conduction characteristic may only be determined by R_{go_on} and R_{g_other_on} according to formula (1). While a desired cutoff characteristic may only be determined by R_{g_off} and R_{g_other_off} according to formula (2).

It should be understood that the structure in FIG. 1 is only an example. The driving circuit of the power components coupled in parallel is not limited to the configuration using diodes and resistors as shown in FIG. 1, but may be any configuration that may provide driving impedances satisfying formulas (1) and (2).

For example, in the example of FIG. 1, the conduction driving impedance and the cutoff driving impedance are designed and described separately by setting diodes for convenience. However, in practice, R_{g_other_on} and R_{g_other_off} may not be designed separately, but combined as a same impedance, as shown in FIG. 2.

FIG. 2 schematically shows a diagram of a parallel semiconductor switch according to another preferred embodiment of the present invention.

Similar to FIG. 1, Q1 is selected as a power component controlling the turn-on transition, and Qn is selected as a power component controlling the turn-off transition. The driving circuits of the control terminals of Q1 and Qn still include two branches. Diodes are configured to allow the two branches to work during a turn-on period of the switch and a turn-off period of the switch, respectively. A difference from the circuit in FIG. 1 is that the driving circuit of the power component not selected to control the turn-on transition and the turn-off transition is simplified, and no longer has two branches. The driving impedances R_{g_other_on} and R_{g_other_off} are combined as a same impedance R_{g_other}.

R_{g_other_on} and R_{g_other_off} in formulas (1) and (2) are replaced by R_{g_other}. The following formulas (3) and (4) may be obtained.

$$\begin{matrix}\frac{{R}_{g\_other}}{{R}_{g\_on}} > \frac{{V}_{drv} - {V}_{th\_min}}{{V}_{drv} - {V}_{th\_max}} • \frac{{C}_{dg\_max}}{{C}_{dg\_min}} & ( 3 ) \\ \frac{{R}_{g\_off}}{{R}_{g\_other}} > \frac{{C}_{dg\_max}}{{C}_{dg\_min}} • \frac{{V}_{th\_max}}{{V}_{th\_min}} & ( 4 )\end{matrix}$$

wherein R_{g_on} is a conduction driving impedance of the power component controlling the turn-on transition of the switch (i.e., Q1 in this example), R_{g_off} is a cutoff driving impedance of the power component controlling the turn-off transition of the switch (i.e., Qn in this example), R_{g_other} is a driving impedance of other power components, V_{drv} is a conduction driving voltage of a power component, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

If the conduction driving impedances satisfy formulas (3) and (4), only the selected power component Q1 may participate in the turn-on transition of the switch, and all other power components coupled in parallel may only be turned on as a zero voltage switch (ZVS) after the turn-on transition; and only the selected power component Qn may participate in the turn-off transition of the switch, and all other power components coupled in parallel may already be turned off as a ZVS before the turn-off transition.

In the above preferred embodiments, MOSFET is used as an example of a power semiconductor component. However, it should be understood that preferred embodiments of the present invention are also applicable to switches including other types of power semiconductor components coupled in parallel, such as, for example, insulated gate bipolar transistors IGBT or Bipolar transistors, etc. In case that other power semiconductor components coupled in parallel are used as the switch, the driving circuit may change accordingly with the type of the power components. However, this still follows the basic idea of the preferred embodiments of the present invention. That is, only one of the plurality of power components is allowed to control a turn-on transition of the switch and only one of the plurality of power components is allowed to control a turn-off transition of the switch, by setting unbalanced driving impedances for the plurality of power components coupled in parallel.

According to a preferred embodiment of the present invention, a corresponding method for controlling a semiconductor switch is further provided. The method includes allowing only one of the plurality of power components to control a turn-on transition of the switch and allowing only one of the plurality of power components to control a turn-off transition of the switch, by setting unbalanced driving impedances for the plurality of power components coupled in parallel.

In some preferred embodiments of the present invention, the power component may be, for example, a metal semiconductor field effect transistor MOSFET. In some preferred embodiments of the present invention, the power component may be, for example, a bipolar transistor BJT. In some preferred embodiments of the present invention, the power component may be, for example, an insulated gate bipolar transistor IGBT.

In some preferred embodiments of the present invention, the allowing only one of the plurality of power components to control a turn-on transition of the switch and the allowing only one of the plurality of power components to control a turn-off transition of the switch includes one of turning on the power component controlling the turn-on transition in response to turning on the switch, and turning on other power components after the power component controlling the turn-on transition is operated in a saturation region; and turning off the power component controlling the turn-off transition after other power components are operated in a cutoff region, in response to turning off the switch.

In some preferred embodiments of the present invention, when the turning on the power component controlling the turn-on transition in response to turning on the switch, and turning on other power components after the power component controlling the turn-off transition is operated in a saturation region is implemented by setting a conduction driving impedance for the power component controlling the turn-on transition to be lower than a conduction driving impedance of other power components. A conduction driving impedance is a driving impedance of a control terminal of a power component in response to turning on the switch.

Optionally, the conduction driving impedances of the plurality of power components coupled in parallel satisfies:

$$\frac{{R}_{g\_other \_on}}{{R}_{g\_on}} > \frac{{V}_{drv} - {V}_{th\_min}}{{V}_{drv} - {V}_{th\_max}} \cdot \frac{{C}_{dg\_max}}{{C}_{dg\_min}} ,$$

wherein R_{go_on} is the conduction driving impedance of the power component controlling the turn-on transition of the switch, R_{g_other_on} is the conduction driving impedance of other power components, V_{drv} is a conduction driving voltage of a power component, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

In some preferred embodiments of the present invention, the turning off the power component controlling the turn-off transition after other power components are operated in a cutoff region, in response to turning off the switch is implemented by setting a cutoff driving impedance for the power component controlling the turn-off transition to be greater than a cutoff driving impedance of other power components. A cutoff driving impedance is a driving impedance of a control terminal of a power component in response to turning off the switch.

Optionally, the cutoff driving impedance of the plurality of power components coupled in parallel satisfies:

$$\frac{{R}_{g\_off}}{{R}_{g\_other \_off}} > \frac{{C}_{dg\_max}}{{C}_{dg\_min}} \cdot \frac{{V}_{th\_max}}{{V}_{th\_min}} ,$$

wherein R_{g_off} is the cutoff driving impedance of the power component controlling the turn-off transition of the switch, R_{g_other_off} is the cutoff driving impedance of other power components, V_{th_min} is a minimum conduction threshold of a power component, V_{th_max} is a maximum conduction threshold of a power component, C_{dg_min} is a minimum reverse transfer capacitance of a power component and C_{dg_max} is a maximum reverse transfer capacitance of a power component.

In some preferred embodiments of the present invention, for the plurality of power components, at least a control terminal of the power component controlling the turn-on transition is coupled to a parallel driving circuit, and the parallel driving circuit includes a first branch including a diode and a first impedance, and a second branch including a diode and a second impedance.

In some preferred embodiments of the present invention, for the plurality of power components, at least a control terminal of the power component controlling the turn-off transition is coupled to a parallel driving circuit, and the parallel driving circuit includes a first branch including a diode and a third impedance, and a second branch including a diode and a fourth impedance.

In some preferred embodiments of the present invention, the power component controlling the turn-on transition of the switch is different from the power component controlling the turn-off transition of the switch.

In other preferred embodiments of the present invention, the power component controlling the turn-on transition of the switch may be same as the power component controlling the turn-off transition of the switch.

According to the methods of preferred embodiments of the present invention, parasitic oscillation in a switch transition may be avoided. Specific details may be referred according to the description of the circuit shown in FIG. 1 and FIG. 2, which will not be repeated here.

It should be noted that in the above description, the technical solutions and advantageous effects of preferred embodiments of the present invention are shown and described by way of example only. The present invention is not limited to the above operations and unit structures. The operations and unit structures may be adjusted and selected as needed. Therefore, some operations and units are not necessary elements of the present invention. Thus, the technical features of the present invention are only limited to the minimum requirements that may achieve the advantageous effects described, and are not limited by the above specific examples of preferred embodiments of the present invention.

According to preferred embodiments of the present invention, parasitic oscillation in a switch transition may be avoided without impedance matching, and the switch transition may provide a relatively small impact on switch characteristics (such as, switch loss and switch speed).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method for controlling a semiconductor switch, the semiconductor switch including a plurality of power components coupled in parallel, the method comprising:
allowing only one of the plurality of power components to control a turn-on transition of the semiconductor switch and allowing only one of the plurality of power components to control a turn-off transition of the semiconductor switch, by setting unbalanced driving impedances of the plurality of power components coupled in parallel.

2. The method of claim 1, wherein the plurality of power components include a metal semiconductor field effect transistor MOSFET, a bipolar transistor BJT, or an insulated gate bipolar transistor IGBT.

3. The method of claim 1, wherein the allowing only one of the plurality of power components to control a turn-on transition of the semiconductor switch and the allowing only one of the plurality of power components to control a turn-off transition of the semiconductor switch includes one of:
turning on the only one of the plurality of power components controlling the turn-on transition in response to turning on the semiconductor switch, and turning on other of the plurality of power components after the only one of the plurality of power components controlling the turn-on transition is operated in a saturation region; and
turning off the only one of the plurality of power components controlling the turn-off transition after other of the plurality of power components are operated in a cutoff region, in response to turning off the semiconductor switch.

4. The method of claim 3, wherein the turning on the only one of the plurality of power components controlling the turn-on transition in response to turning on the semiconductor switch, and the turning on the other of the plurality of power components after the only one of the plurality of power components controlling the turn-off transition is operated in a saturation region is implemented by:
setting a conduction driving impedance for the only one of the plurality of power components controlling the turn-on transition to be lower than a conduction driving impedance of other of the plurality of power components, wherein a conduction driving impedance is a driving impedance of a control terminal of a power component of the plurality of power components in response to turning on the semiconductor switch.

5. The method of claim 4, wherein the conduction driving impedances of the plurality of power components coupled in parallel satisfies:
$$\frac{{R}_{g\_other \_on}}{{R}_{g\_on}} > \frac{{V}_{drv} - {V}_{th\_min}}{{V}_{drv} - {V}_{th\_max}} \cdot \frac{{C}_{dg\_max}}{{C}_{dg\_min}} ,$$
wherein R_{g_on} is the conduction driving impedance of the only one of the plurality of power components controlling the turn-on transition of the semiconductor switch, R_{g_other_on} is the conduction driving impedance of the other of the plurality of power components, V_{drv} is a conduction driving voltage of a power component of the plurality of power components, V_{th_min} is a minimum conduction threshold of a power component of the plurality of power components, V_{th_max} is a maximum conduction threshold of a power component of the plurality of power components, C_{dg_min} is a minimum reverse transfer capacitance of a power component of the plurality of power components, and C_{dg_max} is a maximum reverse transfer capacitance of a power component of the plurality of power components.

6. The method of claim 3, wherein the turning off the only one of the plurality of power components controlling the turn-off transition after other of the plurality of power components are operated in a cutoff region, in response to turning off the semiconductor switch is implemented by:
setting a cutoff driving impedance for the only one of the plurality of power components controlling the turn-off transition to be greater than a cutoff driving impedance of the other of the plurality of power components, wherein a cutoff driving impedance is a driving impedance of a control terminal of a power component of the plurality of power components in response to turning off the semiconductor switch.

7. The method of claim 6, wherein the cutoff driving impedance of the plurality of power components coupled in parallel satisfies:
$$\frac{{R}_{g\_off}}{{R}_{g\_other \_off}} > \frac{{C}_{dg\_max}}{{C}_{dg\_min}} \cdot \frac{{V}_{th\_max}}{{V}_{th\_min}} ,$$
wherein R_{g_off} is the cutoff driving impedance of the only one of the plurality of power components controlling the turn-off transition of the semiconductor switch, R_{g_other_off} is the cutoff driving impedance of the other of the plurality of power components, V_{th_min} is a minimum conduction threshold of a power component of the plurality of power components, V_{th_max} is a maximum conduction threshold of a power component of the plurality of power components, C_{dg_min} is a minimum reverse transfer capacitance of a power component of the plurality of power components, and C_{dg_max} is a maximum reverse transfer capacitance of a power component of the plurality of power components.

8. The method of claim 1, wherein for the plurality of power components, at least a control terminal of the only one of the plurality of power components controlling the turn-on transition is coupled to a parallel driving circuit, and the parallel driving circuit includes:
a first branch including a diode and a first impedance; and
a second branch including a diode and a second impedance.

9. The method of claim 1, wherein for the plurality of power components, at least a control terminal of the only one of the plurality of power components controlling the turn-off transition is coupled to a parallel driving circuit, and the parallel driving circuit includes:
a first branch including a diode and a third impedance; and
a second branch including a diode and a fourth impedance.

10. The method of claim 1, wherein the only one of the plurality of power components controlling the turn-on transition of the semiconductor switch is different from the only one of the plurality of power components controlling the turn-off transition of the semiconductor switch.

11. A semiconductor switch comprising a plurality of power components coupled in parallel, wherein
the plurality of power components coupled in parallel include unbalanced control-terminal driving impedances, only one of the plurality of power components is allowed to control a turn-on transition of the semiconductor switch and only one of the plurality of power components is allowed to control a turn-off transition of the semiconductor switch.

12. The semiconductor switch of claim 11, wherein the plurality of power components include a metal semiconductor field effect transistor MOSFET, a bipolar transistor BJT, or an insulated gate bipolar transistor IGBT.

13. The semiconductor switch of claim 11, wherein a conduction driving impedance of the only one of the plurality of power components controlling the turn-on transition is lower than a conduction driving impedance of other of the plurality of power components, wherein a conduction driving impedance is a driving impedance of a control terminal of a power component of the plurality of power components in response to turning on the semiconductor switch.

14. The semiconductor switch of claim 13, wherein the conduction driving impedances of the plurality of power components coupled in parallel satisfies:
$$\frac{{R}_{g\_other \_on}}{{R}_{g\_on}} > \frac{{V}_{drv} - {V}_{th\_min}}{{V}_{drv} - {V}_{th\_max}} \cdot \frac{{C}_{dg\_max}}{{C}_{dg\_min}} ,$$
wherein R_{go_on} is the conduction driving impedance of the only one of the plurality of power components controlling the turn-on transition of the semiconductor switch, R_{g_other_on} is the conduction driving impedance of the other of the plurality of power components, V_{drv} is a conduction driving voltage of a power component of the plurality of power components, V_{th_min} is a minimum conduction threshold of a power component of the plurality of power components, V_{th_max} is a maximum conduction threshold of a power component of the plurality of power components, C_{dg_min} is a minimum reverse transfer capacitance of a power component of the plurality of power components, and C_{dg_max} is a maximum reverse transfer capacitance of a power component of the plurality of power components.

15. The semiconductor switch of claim 11, wherein a cutoff driving impedance for the only one of the plurality of power components controlling the turn-off transition is greater than a cutoff driving impedance of other of the plurality of power components, wherein a cutoff driving impedance is a driving impedance of a control terminal of a power component of the plurality of power components in response to turning off the semiconductor switch.

16. The semiconductor switch of claim 15, wherein the cutoff driving impedance of the plurality of power components coupled in parallel satisfies:
$$\frac{{R}_{g\_off}}{{R}_{g\_other \_off}} > \frac{{C}_{dg\_max}}{{C}_{dg\_min}} \cdot \frac{{V}_{th\_max}}{{V}_{th\_min}} ,$$
wherein R_{g_off} is the cutoff driving impedance of the only one of the plurality of power components controlling the turn-off transition of the semiconductor switch, R_{g_other_off} is the cutoff driving impedance of other power components of the plurality of power components, V_{th_min} is a minimum conduction threshold of a power component of the plurality of power components, V_{th_max} is a maximum conduction threshold of a power component of the plurality of power components, C_{dg_min} is a minimum reverse transfer capacitance of a power component of the plurality of power components, and C_{dg_max} is a maximum reverse transfer capacitance of a power component of the plurality of power components.

17. The semiconductor switch of claim 11, wherein for the plurality of power components, at least a control terminal of the only one of the plurality of power components controlling the turn-on transition is coupled to a parallel driving circuit, and the parallel driving circuit includes:
a first branch including a diode and a first impedance; and
a second branch including a diode and a second impedance.

18. The semiconductor switch of claim 11, wherein for the plurality of power components, at least a control terminal of the only one of the plurality of power components controlling the turn-off transition is coupled to a parallel driving circuit, and the parallel driving circuit includes:
a first branch including a diode and a third impedance; and
a second branch including a diode and a fourth impedance.

19. The semiconductor switch of claim 11, wherein the only one of the plurality of power components controlling the turn-on transition of the semiconductor switch is different from the only one of the plurality of power components controlling the turn-off transition of the semiconductor switch.
